(19) United States
(12) Patent Application Publication
(10) Pub. No.: US 2024/0047280 A1
(43) Pub. Date: Feb. 8, 2024

(54) MANUFACTURING METHOD OF DISPLAY PANEL, AND DETECTION AND BONDING APPARATUS FOR A MICRO ELEMENT

(71) Applicant: Tianma Advanced Display Technology Institute (Xiamen) Co., Ltd., Xiamen (CN)

(72) Inventors: Kerui XI, Xiamen (CN); Jiansheng ZHONG, Xiamen (CN); Feng QIN, Xiamen (CN); Xuhui PENG, Xiamen (CN)

(73) Assignee: Tianma Advanced Display Technology Institute (Xiamen) Co., Ltd., Xiamen (CN)

(21) Appl. No.: 18/381,798

(22) Filed: Oct. 19, 2023

(30) Foreign Application Priority Data
Jun. 30, 2023 (CN) 202310798587.4

(51) Int. Cl. H01L 21/66; H01L 25/16; H01L 23/00

(52) U.S. Cl. CPC H01L 22/22; H01L 25/167; H01L 24/81; H01L 24/16; H01L 24/13; H01L 24/95; H01L 24/75; H01L 2224/16148; H01L 2924/12041; H01L 2924/1426; H01L 2224/81224; H01L 2224/13111; H01L 2224/13109; H01L 2224/13144; H01L 2224/81005; H01L 2224/95001; H01L 2224/75261; H01L 2224/7598

(57) ABSTRACT

Provided are a manufacturing method of a display panel and a detection and bonding apparatus for a micro element. The manufacturing method of a display panel includes providing a first transfer substrate and performing a detection and bonding process. The first transfer substrate includes a first temporary carrier plate and a plurality of micro elements disposed on the first temporary carrier plate. The step of performing a detection and bonding process includes placing the first transfer substrate and an array substrate opposite to each other so that the drive electrode of the micro element is in contact with a connection electrode on the array substrate; supplying power to the array substrate to conduct the plurality of micro elements; and acquiring a first pattern formed by each illuminated micro element, and bonding a drive electrode of the each illuminated micro element with the connection electrode.

### CROSS-REFERENCE TO RELATED APPLICATION(S)

This application claims priority to Chinese Patent Application No. 202310798587.4 filed Jun. 30, 2023, the disclosure of which is incorporated herein by reference in its entirety.

### TECHNICAL FIELD

The present application relates to the technical field of display and, in particular, to a manufacturing method of a display panel, and a detection and bonding apparatus for a micro element.

### BACKGROUND

For a micro light-emitting diode (microLED), each micro element is prepared and then needs to be transferred to an array substrate to be bonded so that the display panel is integrally formed.

Currently, the manufactured micro element is typically placed on a temporary carrier plate which is placed opposite to the array substrate so that a drive electrode of the micro element and a connection electrode on the array substrate are butted and bonded. After the bonding of micro elements is completed, an unilluminated micro element after detection is removed by laser and is replaced.

However, in the process of removing the unilluminated micro element, it may be necessary to repair the connection electrode and re-fill the solder, which easily causes damage to other circuits, not only complicating the repair process, but also leading to the low product yield.

### SUMMARY

Embodiments of the present application provide a manufacturing method of a display panel, and a detection and bonding apparatus for a micro element, which can reduce the process difficulty and improve the product yield.

In an aspect, an embodiment of the present application provides a manufacturing method of a display panel. The method includes: providing a first transfer substrate, performing a detection and bonding process, providing a second transfer substrate, and performing the detection and bonding process again.

The first transfer substrate includes a first temporary carrier plate and a plurality of micro elements disposed on the first temporary carrier plate, and a micro element of the plurality of micro elements includes a drive electrode.

The step of performing a detection and bonding process includes the steps described below.

The first transfer substrate and an array substrate are placed opposite to each other so that the drive electrode of the micro element is in contact with a connection electrode on the array substrate.

Power is supplied to the array substrate to conduct the plurality of micro elements.

A first pattern formed by each illuminated micro element is acquired, and a drive electrode of the each illuminated micro element is boned with the connection electrode according to the first pattern to form a first bonding pattern.

The first temporary carrier plate is removed to take away a non-bonded micro element to form a first non-bonding pattern on the array substrate.

The second transfer substrate includes a second temporary carrier plate and a plurality of supplementary micro elements disposed on the second temporary carrier plate, and relative positions of the plurality of supplementary micro elements on the second transfer substrate are consistent with the first non-bonding pattern.

The detection and bonding process is performed again so that a supplementary micro element of the plurality of supplementary micro elements is provided for a position included in the first non-bonding pattern of the array substrate.

In another aspect, an embodiment of the present application provides a detection and bonding apparatus for a micro element. The detection and bonding apparatus for a micro element includes a detection device and an execution device. The detection device includes an optical lens and a display screen, the optical lens and the display screen are connected to each other, and the detection device is configured to acquire information about a first pattern formed by a position of each illuminated micro element. The execution device includes laser instrument and is configured to receive the information about the first pattern provided by the detection device and to bond a micro element at a corresponding position according to the information about the first pattern.

The embodiments of the present application provide a manufacturing method of a display panel and a detection and bonding apparatus for a micro element. A plurality of micro elements are transferred to an array substrate so that drive electrodes of the micro elements are in contact with connection electrodes on the array substrate. Power is supplied to the array substrate first. A lighting test is performed after the micro elements are conducted. Then, the illuminated micro elements are selected to be bonded, and abnormal micro elements are directly taken away from the array substrate. Therefore, the bonding process is more targeted, avoiding the case where the poor micro elements are removed after all the micro elements are bonded, thus reducing the process difficulty caused by later repair, simplifying the process flow steps, improving the preparation efficiency of the display panel, preventing damage to components in the process of removing the micro elements, and improving the overall yield of products.

### BRIEF DESCRIPTION OF DRAWINGS

Features, advantages, and technical effects of example embodiments of the present application will be described below with reference to the drawings.

FIG. 1 is a flowchart of a manufacturing method of a display panel according to an embodiment of the present application;

FIG. 2 is a structural view of a first transfer substrate according to an embodiment of the present application;

FIG. 3 is a plan view of the first transfer substrate according to an embodiment of the present application;

FIG. 4 is a plan view of an array substrate according to an embodiment of the present application;

FIG. 5 is a sectional view illustrating films of the array substrate according to an embodiment of the present application;

FIG. 6 is a view illustrating a manufacturing process of the display panel according to an embodiment of the present application;

FIG. 7 is a view illustrating a manufacturing process of the display panel according to an embodiment of the present application;

FIG. 8 is a partial enlarged view of a part A of FIG. 7;

FIG. 9 is a plan view of the first transfer substrate butted with the array substrate according to an embodiment of the present application;

FIG. 10 is a view illustrating a manufacturing process of the display panel according to an embodiment of the present application;

FIG. 11 is a plan view of the array substrate according to an embodiment of the present application;

FIG. 12 is a structural view of a second transfer substrate according to an embodiment of the present application;

FIG. 13 is a plan view of the second transfer substrate according to an embodiment of the present application;

FIG. 14 is a view illustrating a manufacturing process of the display panel according to an embodiment of the present application;

FIG. 15 is a view illustrating a manufacturing process of the display panel according to an embodiment of the present application;

FIG. 16 is a view illustrating a manufacturing process of the display panel according to an embodiment of the present application;

FIG. 17 is a structural view of another first transfer substrate according to an embodiment of the present application;

FIG. 18 is a view illustrating a manufacturing process of the display panel according to an embodiment of the present application;

FIG. 19 is a view illustrating a manufacturing process of the display panel according to an embodiment of the present application;

FIG. 20 is a view illustrating a manufacturing process of the display panel according to an embodiment of the present application;

FIG. 21 is another plan view of the first transfer substrate butted with the array substrate according to an embodiment of the present application;

FIG. 22 is a view illustrating a manufacturing process of the display panel according to an embodiment of the present application; and

FIG. 23 is a view illustrating a manufacturing process of the display panel according to an embodiment of the present application.

### REFERENCE LIST

10 first transfer substrate
1 first temporary carrier plate
2 micro element
2a first element
2b second element
2c third element
21 drive electrode
22 connection electrode
22a anode
22b cathode
20 array substrate
M first bonding pattern
N first non-bonding pattern
N1 sub-region
30 second transfer substrate
3 second temporary carrier plate
4 supplementary micro element
5 temporary material layer
6 source
7 drain
8 gate
9 active layer

In the drawings, like reference numerals refer to like components. The drawings are not drawn to actual scale.

### DETAILED DESCRIPTION

Features and example elements in various aspects of the present application are described hereinafter in detail. Details are set forth below to facilitate a thorough understanding of the present application. To those skilled in the art, apparently, the present application may be implemented with no need for some of these specific details. The description of the embodiments hereinafter is intended merely to provide a better understanding of the present application through examples of the present application. In the drawings and the description hereinafter, at least parts of the well-known structures and techniques are not shown in order to avoid unnecessary ambiguity to the present application; moreover, the size of some structures may be exaggerated for clarity. The features, structures or characteristics described hereinafter may be incorporated in one or more embodiments in any suitable manner.

The orientation words used in the following description refer to the directions shown in the figures and are not intended to limit the manufacturing method of a display panel and the specific structures of the detection and bonding apparatus for a micro element provided in the present application. In the description of the present application, it is further to be noted that terms “mounted” and “connected” are to be understood in a broad sense unless otherwise expressly specified and limited. For example, the term “connected” may refer to “securely connected”, “detachably connected” or “integrally connected” or may refer to “connected directly” or “connected indirectly”. For those skilled in the art, the preceding terms in the present application can be construed depending on specific contexts.

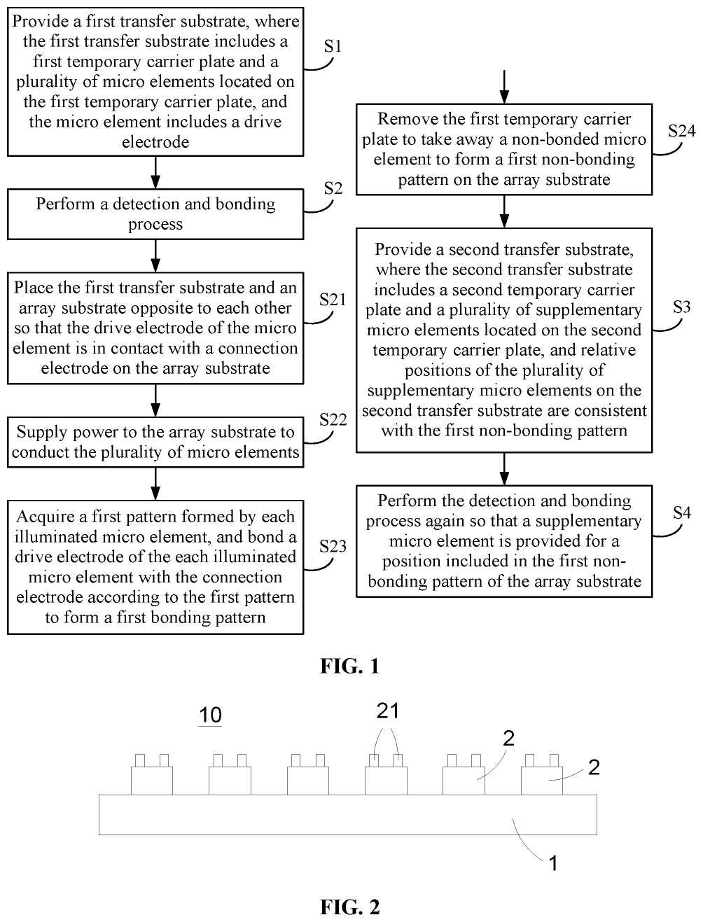

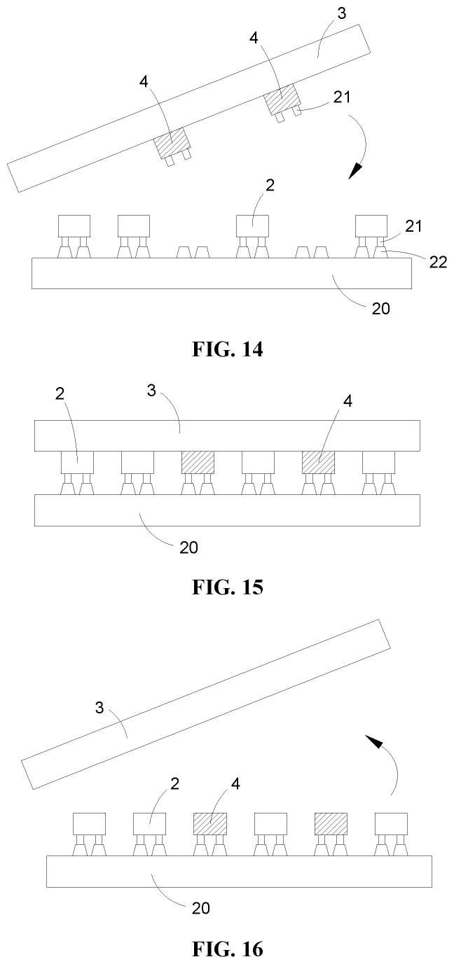

For a better understanding of the present application, a manufacturing method of a display panel and a detection and bonding apparatus for a micro element provided in the embodiments of the present application will be described below in detail with reference to FIG. 1 to FIG. 23.

With reference to FIG. 1, an embodiment of the present application provides a manufacturing method of a display panel. The method includes the steps described below.

In S1, a first transfer substrate 10 is provided. The first transfer substrate 10 includes a first temporary carrier plate 1 and a plurality of micro elements 2 disposed on the first temporary carrier plate 1, and the micro element 2 includes a drive electrode 21.

In S2, a detection and bonding process is performed. The process includes the steps described below.

In S21, the first transfer substrate 10 and an array substrate 20 are placed opposite to each other so that the drive electrode 21 of the micro element 2 is in contact with a connection electrode 22 on the array substrate 20.

In S22, power is supplied to the array substrate 20 to conduct the plurality of micro elements 2.

In S23, a first pattern formed by each illuminated micro element 2 is acquired, and a drive electrode 21 of the each illuminated micro element 2 is boned with the connection electrode 22 according to the first pattern to form a first bonding pattern M.

In S24, the first temporary carrier plate 1 is removed to take away a non-bonded micro element 2 to form a first non-bonding pattern N on the array substrate 20.

In S3, a second transfer substrate 30 is provided. The second transfer substrate 30 includes a second temporary carrier plate 3 and a plurality of supplementary micro elements 4 disposed on the second temporary carrier plate 3, and relative positions of the plurality of supplementary micro elements 4 on the second transfer substrate 30 are consistent with the first non-bonding pattern N.

In S4, the detection and bonding process is performed again so that a supplementary micro element 4 is provided for a position included in the first non-bonding pattern N of the array substrate 20.

In step S1, the plurality of micro elements 2 are molded on a growth substrate. Optionally, the growth substrate may be a sapphire substrate. The micro element 2 includes a red light-emitting element, a green light-emitting element and a blue light-emitting element. The green light-emitting element and the blue light-emitting element may be directly molded on the sapphire substrate.

After the plurality of micro elements 2 are molded, other processing processes may be performed according to requirements. The plurality of micro elements 2 may be transferred to an intermediate carrier plate to complete processing and finally are transferred from the intermediate carrier plate to the first temporary carrier plate 1 to prepare for assembly detection.

The plurality of micro elements 2 on the intermediate carrier plate may be separated from the intermediate carrier plate in a manner of laser release and dropped to the first temporary carrier plate 1, thereby completing the transfer process of the micro elements 2. The red light-emitting element, the green light-emitting element and the blue light-emitting element have different sizes and arrangement positions. The plurality of micro elements 2 may be arranged according to a preset array arrangement mode to meet different product models and display requirements.

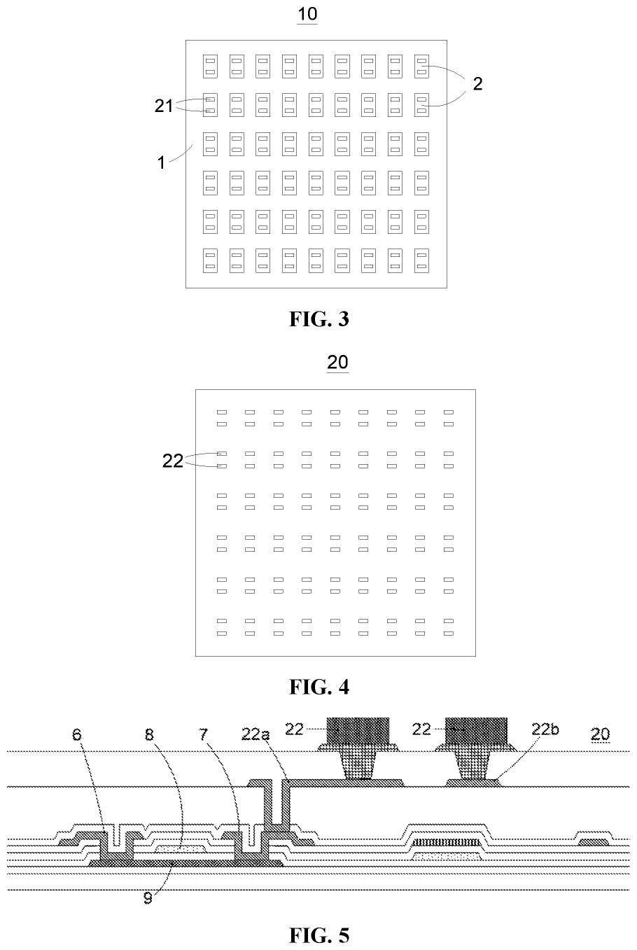

After the micro elements 2 are transferred from the intermediate carrier plate to the first temporary carrier plate 1, the first temporary carrier plate 1 and the plurality of micro elements 2 together form the first transfer substrate 10. Specifically, the micro elements 2 are assembled with the array substrate 20 through the drive electrodes 21 of the micro elements 2, as shown in FIG. 2 and FIG. 3.

For the structure of the array substrate 20, the array substrate 20 has a plurality of sets of connection electrodes 22 to be butted with the drive electrodes 21 of the micro elements 2. For the structure views of the array substrate 20, reference may be made to FIG. 4 and FIG. 5. The array substrate 20 has a transistor (TFT), a capacitor, a signal line and other structures. The transistor specifically includes a source 6, a drain 7 and a gate 8. The source 6 and the drain 7 are separately connected to an active layer 9. The active layer 9 may be a semiconductor layer and a plurality of insulating layers are spaced in the middle. An anode 22a is connected to the drain 7 through a via on the planarization layer. The anode 22a provides an anode potential to one of the connection electrodes 22 and a cathode 22b provides a cathode potential to the other connection electrode 22.

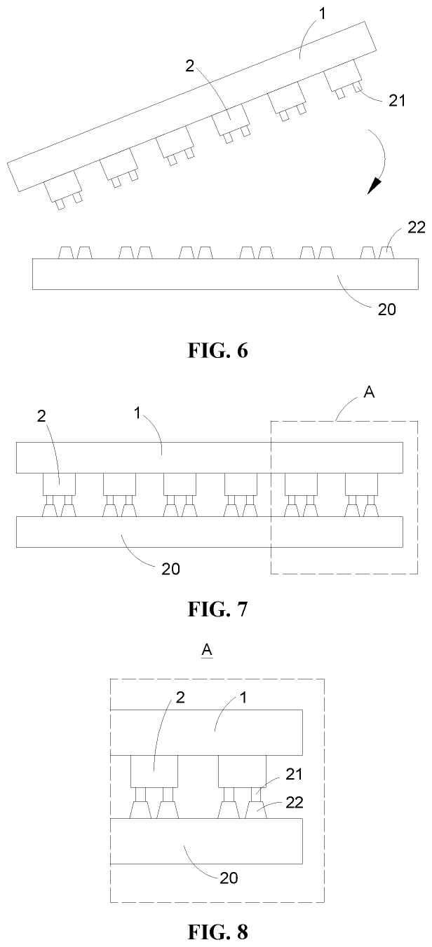

In step S21, with reference to FIG. 6 to FIG. 8, the molded first transfer substrate 10 is moved to the array substrate 20 and placed opposite to the array substrate 20. Optionally, the first transfer substrate 10 may be transported and moved by using a mechanical arm or other equipment structure, so that the drive electrodes 21 of each micro element 2 are in one-to-one contact with the connection electrodes 22 on the array substrate 20, ensuring that each micro element 2 is connected to the array substrate 20. The contact here may be understood as physical contact. That is, if the first transfer substrate 10 and the array substrate are separated from each other, the drive electrode 21 of the micro element 2 and the connection electrode 22 of the array substrate 20 may be separated naturally. It is enough to achieve electrical conduction between the drive electrode 21 and the connection electrode 22 through the contact between the drive electrode 21 and the connection electrode 22. Under the guidance of a high-precision apparatus, the drive electrode 21 of the micro element 2 is precisely butted with the connection electrode 22 of the array substrate 20.

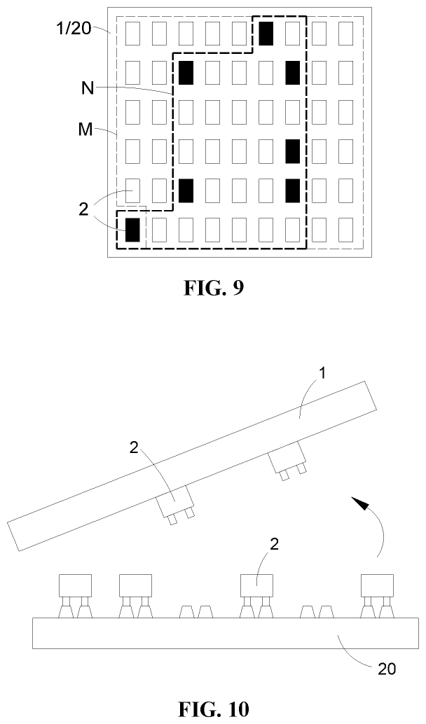

In steps S22 and S23, after the micro elements 2 are butted with the array substrate 20, the array substrate 20 is supplied with power first, and after all the micro elements 2 are conducted, a lighting test process is performed. Each illuminated micro element 2 among all the micro elements 2 form a first pattern. Selectively, the illuminated micro elements 2 according to the first pattern need to be bonded and as a whole form the first bonding pattern M on the array substrate 20. That is, the first bonding pattern M refers to the pattern formed by each bonded micro element 2. No processing is performed on the unilluminated micro element 2, that is, bonding is not performed on the unilluminated micro element 2. As shown in FIG. 9, the parts marked in black refer to the unilluminated micro elements 2. FIG. 9 is a top view of the first transfer substrate 10 and the array substrate 20 which are placed opposite to each other. The micro elements 2 should also be covered by the first temporary carrier plate 1. In order to clearly illustrate different micro elements 2, the first temporary carrier plate 1 is subjected to perspective processing. The abnormal situation of the micro elements 2 is random. FIG. 9 merely schematically shows the positions of the abnormal micro elements 2 and merely illustrates a possible situation as an example, which is not intended to limit the present solution. The first bonding pattern M has many other possibilities and is not listed one by one in the present solution.

In FIG. 9, the first bonding pattern M may refer to a pattern formed by each white rectangle (or unfilled rectangle) in the dashed line box, and the first non-bonding pattern N may refer to a pattern formed by each black rectangle in the dashed line box.

Optionally, both the drive electrode 21 of the micro element 2 and the connection electrode 22 of the array substrate 20 are made of metal, the bonding process is completed in a manner of laser welding so that at least one of the drive electrode 21 or the connection electrode 22 is melted, and after curing, the drive electrode 21 and the connection electrode 22 are connected together to complete the bonding process.

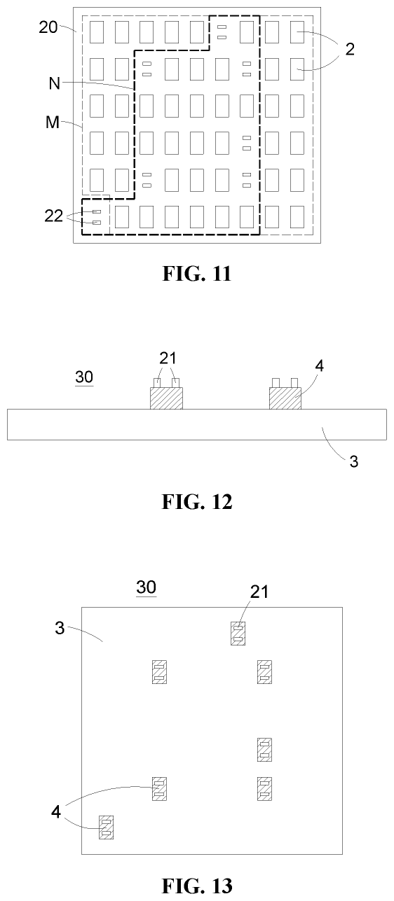

In step S24, the unilluminated micro elements 2 are not bonded with the array substrate 20 and remain on the first temporary carrier plate 1, so after the bonding process is completed, the first temporary carrier plate 1 is removed to take away the unilluminated micro elements 2, and a first non-bonding pattern N complementary to the first bonding pattern M is formed on the array substrate 20, which are shown in FIG. 10 and FIG. 11.

Optionally, in the case where the plurality of transferred micro elements 2 are all illuminated on the array substrate 20, all of the micro elements 2 need to be bonded. In this case, merely the first bonding pattern M is formed, and no first non-bonding pattern N is formed.

In step S3, supplementary processing is performed for the first non-bonding pattern N. The second transfer substrate 30 is formed according to the preceding molding step and according to the position of the first non-bonding pattern N. A plurality of supplementary micro elements 4 on the second temporary carrier plate 3 are placed corresponding to the first non-bonding pattern N on the array substrate 20, and then the supplementary micro elements 4 are butted with the array substrate 20, as shown in FIG. 12 to FIG. 16.

In step S4, the procedures of step S2 are repeated to provide the supplementary micro element 4 for the first non-bonding pattern N.

The number of repetitions of each procedure of step S2 may be set according to specific requirements. For example, each procedure of step S2 may be repeated until all micro elements 2 on the array substrate 20 can be illuminated and bonded, thereby completing the manufacturing process of the display panel. Alternatively, each procedure of step S2 may be repeated until the ratio of the illuminated micro elements (the ratio of the number of illuminated micro elements to a preset total number of micro elements) of the display panel reaches a target yield.

It is to be noted that the supplementary micro element 4 and the micro element 2 may be micro elements having the same structure, and the names are different merely to distinguish the order in which the supplementary micro element 4 and the micro element 2 are arranged. In other embodiments, the supplementary micro element 4 and the micro element 2 may also be micro elements having different structures.

The embodiments of the present application provide the manufacturing method of a display panel. A plurality of micro elements 2 are transferred to the array substrate 20 so that drive electrodes 21 of the micro elements 2 are in contact with connection electrodes 22 on the array substrate 20. Power is supplied to the array substrate 20 first. A lighting test is performed after the micro elements 2 are conducted. Then, selectively, the illuminated micro elements 2 are bonded. Therefore, the bonding process is more targeted, avoiding the case where the poor micro elements 2 are removed after all the micro elements 2 are bonded, thus reducing the process difficulty caused by later repair, simplifying the process flow steps, improving the preparation efficiency of the display panel, preventing damage to components in the process of removing the micro elements 2, and improving the overall yield of products. In addition, since the connection electrode 22 used to be bonded with the supplementary micro element 4 is not subjected to laser processing and is not damaged by the laser, the connection electrode 22 can be bonded smoothly with the supplementary micro element 4. Therefore, positions for redundant electrodes playing a repairing function may not be provided in the array substrate 20, thus saving the layout region of the connection electrode 22 and facilitating the high-resolution display. Moreover, in the display panel prepared by adopting the technical solution of the present application, no obvious structural difference exists between the micro element 2 and the supplementary micro element 4, and the display panel does not have a structural difference caused by repairing damage in the related art. For example, the position of the repaired element is different from the original bonding position, or the repaired micro element has a different bonding structure from the original micro element. The structural difference easily causes uneven display. Therefore, the display panel of the present application has excellent display uniformity.

In an optional embodiment, after the detection and bonding process is performed again, a poor micro element that is not illuminated may appear again, thereby forming on the array substrate 20 a second non-bonding pattern which is different from the first non-bonding pattern N.

Optionally, after the supplementary micro elements 4 are carried by the second temporary carrier plate 3 to be butted according to the first non-bonding pattern N and to be supplied with power, the illuminated micro elements 2 are bonded, and the unilluminated micro elements 2 form a second non-bonding pattern at corresponding positions on the array substrate 20. It is understood that the second non-bonding pattern is a part of the first non-bonding pattern N. Similarly, the preceding detection process is repeated until all the micro elements 2 are bonded.

The embodiments of the present application provide a manufacturing method of a display panel. The second non-bonding pattern is obtained from the first non-bonding pattern N, so that the detection and bonding process of part of the micro elements 2 is more pertinently completed. The detection and bonding operations are repeated, better ensuring the yield of products.

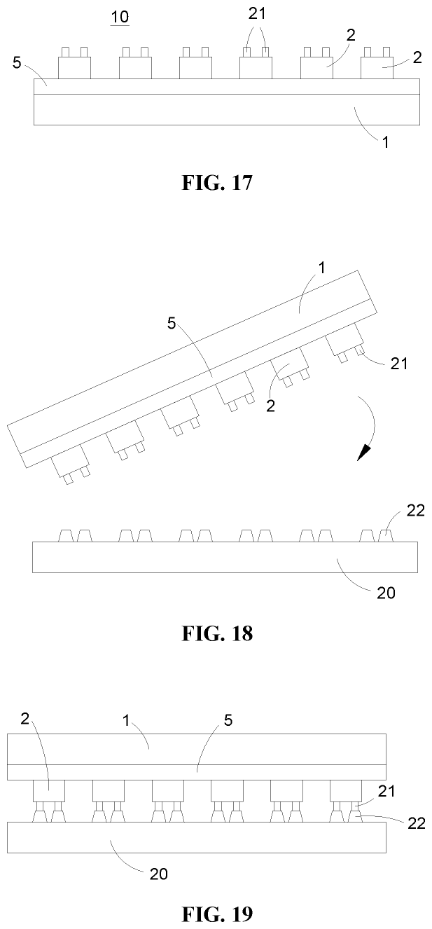

In an optional embodiment, with reference to FIG. 17 to FIG. 19, the steps described below are further included.

A temporary material layer 5 is configured on the first temporary carrier plate 1, and the plurality of micro elements 2 are configured on the temporary material layer 5. The temporary material layer 5 has viscosity and elasticity.

The step of placing the first transfer substrate 10 and the array substrate 20 opposite to each other includes extruding the micro element 2 with the temporary material layer 5 so that the drive electrode 21 of the micro element 2 is in sufficient contact with the connection electrode 22 on the array substrate 20.

Optionally, the temporary material layer 5 may be configured on the first temporary carrier plate 1, and the plurality of micro elements 2 are dropped onto the temporary material layer 5 from the intermediate carrier plate. The temporary material layer 5 needs to have certain viscosity and elasticity. The micro elements 2 are adhered to the temporary material layer 5 by using the viscosity, which is convenient for transfer. The temporary material layer 5 may be made of organic silica gel and the like.

When the first transfer substrate 10 and the array substrate 20 are placed opposite to each other, pressure may be applied to the first transfer substrate 10, so that a plurality of micro elements 2 are integrally pressed through the temporary material layer 5, and the drive electrodes 21 of the micro elements 2 are in close contact with the connection electrodes 22 on the array substrate 20. The temporary material layer 5 has elasticity, facilitating adjustment of the extrusion force on the micro elements 2 through the temporary material layer 5 when the pressure is applied to the first transfer substrate 10, and preventing the extrusion force on the micro elements 2 from being too large on the basis of ensuring that the drive electrodes 21 of the micro elements 2 are in close contact with the connection electrodes 22 on the array substrate 20.

Compared with no temporary material layer 5, this embodiment provides the temporary material layer 5 so that the micro elements 2 can be in sufficient contact with the array substrate 20. That is, the drive electrodes 21 and the connection electrodes 22 are butted and fit with each other without gap generated. After the array substrate 20 is supplied with power, the normal conduction of the micro elements 2 is ensured. The detection error caused by poor contact between the micro elements 2 and the array substrate 20 is avoided. Normal illumination of qualified micro elements 2 are prevented from being affected by the factor of open circuit between the micro element 2 and the array substrate 20. Therefore, the accuracy of the detection process is improved.

In an optional embodiment, the step of configuring the temporary material layer 5 on the first temporary carrier plate 1 includes uniformly coating a material on the first temporary carrier plate 1 to form the temporary material layer 5.

Optionally, the required temporary material may be dipped with a tool such as a brush and then applied to the first temporary carrier plate 1. Then, the temporary material is evenly distributed on the first temporary carrier plate 1 to form the temporary material layer 5.

Alternatively, the material is dripped onto the first temporary carrier plate 1 to form the temporary material layer 5 in a manner of spin coating. In the manner of spin coating, a larger coverage area can be formed on the first temporary carrier plate 1, so that the temporary material is spread out and evenly distributed on the first temporary carrier plate 1 and finally the temporary material layer 5 is formed.

The embodiment of the present application provides the manufacturing method of a display panel. The temporary material layer 5 is more evenly distributed on the first temporary carrier plate 1 by using the preceding method in which the temporary material layer 5 is molded on the first temporary carrier plate 1, achieving a full coverage of all micro elements 2, ensuring more uniform extrusion force on the plurality of micro elements 2, and improving the accuracy of the detection process.

Optionally, the step of configuring the temporary material layer 5 on the first temporary carrier plate 1 includes controlling a thickness of the temporary material layer 5 to remain at 5 μm to 20 μm.

The thickness of the temporary material layer 5 on the first temporary carrier plate 1 is set to remain at 5 μm to 20 μm, so that the temporary material layer 5 exerts the adhesion effect on the micro elements 2 and at the same time can form an appropriate extrusion force on the micro elements 2 butted. The viscosity and elasticity of the temporary material layer 5 can be fully exerted.

In an optional embodiment, before the first temporary carrier plate 1 is removed to take away the non-bonded micro element 2, the method further includes: at least reducing viscosity of a position of the temporary material layer 5 where a bonded micro element 2 is located so that a bonding force between the micro element 2 and the array substrate 20 is greater than an adhesive force between the micro element 2 and the temporary material layer 5.

In consideration that in step S24 the first temporary carrier plate 1 needs to be removed after the bonding so as to take away the non-bonded micro element 2, it is necessary to ensure that the bonding force at the joint of the connection electrode 22 and the drive electrode 21 of the illuminated micro element 2 is greater than the adhesive force between the illuminated micro element 2 and the temporary material layer 5, so that the bonded micro element 2 can be smoothly separated from the temporary material layer 5 without being taken away after the first temporary carrier plate 1 is removed.

Optionally, the temporary material layer 5 may be made of a photosensitive material whose viscosity can be reduced after being subjected to illumination. Therefore, during the preceding lighting test, the viscosity of the position of the temporary material layer 5 where the illuminated micro element 2 is located is reduced due to the illumination. After the illuminated micro element 2 is bonded, the adhesive force on the illuminated micro element 2 is less than the bonding force on the micro element 2. Therefore, the separation of the illuminated micro element 2 from the temporary material layer 5 is facilitated. The viscosity of the position of the temporary material layer 5 where the unilluminated micro element 2 is located is not affected and the unilluminated micro element 2 can be taken away together with the first temporary carrier plate 1.

The embodiment of the present application provides the manufacturing method of a display panel. The viscosity of the positions of the temporary material layer 5 where the illuminated micro element 2 and the unilluminated micro element 2 are located is adjusted, so that the illuminated micro element 2 is easier to be separated and complete bonding and the unilluminated micro element is easy to be taken away smoothly. The adjustment is pertinently completed, the difficulty of the process flow is reduced, and the transportation process is easier to achieve.

In an optional embodiment, the step of at least reducing the viscosity of the position of the temporary material layer 5 where the bonded micro element 2 is located includes: reducing viscosity of the entire temporary material layer 5 and the viscosity of the temporary material layer 5 being greater than zero.

Compared with the preceding adjustment performed on the viscosity of part of the temporary material layer 5, the adjustment in this embodiment is targeted for the viscosity of the entire temporary material layer 5. Optionally, the viscosity of the entire temporary material layer can be reduced through a change in the ambient temperature and humidity.

In this case, the bonding force is greater than the adhesive force for the bonded micro element 2, facilitating the separation of the micro element 2. At the same time, it is to be noted that even though the viscosity of the entire temporary material layer 5 is reduced, it is necessary to ensure that the viscosity of the entire temporary material layer 5 is greater than zero, so that the temporary material layer 5 can continue to form an adhesive force on the non-bonded micro element 2 and smoothly take away the non-bonded micro element 2.

The embodiment of the present application provides the manufacturing method of a display panel. The viscosity of the entire temporary material layer 5 is reduced, so that the bonding force is fully ensured to be greater than the adhesive force for the micro element 2 and the bonded micro element 2 is more ensured to be separated from the temporary material layer 5.

In an optional embodiment, the step of acquiring the first pattern formed by each illuminated micro element 2 includes using a detection device to acquire information about the first pattern.

The step of bonding the drive electrode 21 of the each illuminated micro element 2 with the connection electrode 22 according to the first pattern includes the following: the detection device transmits the information about the first pattern to an execution device, and the execution device bonds a micro element 2 at positions corresponding to the first pattern according to the information about the first pattern.

Optionally, after the array substrate 20 is supplied with power, the illuminated micro

elements 2 form the first pattern as a whole, and the detection device can capture and display information such as the shape and position of the first pattern, so that a worker can directly observe the information about the first pattern, facilitating subsequent bonding and other operations.

Optionally, the detection device may be connected to the execution device through a patch cord. The information about the first pattern is acquired by the detection device and then may be transmitted to the execution device through the patch cord. The execution device is ordered to bond the illuminated micro elements 2 according to the first pattern. Of course, the detection device and the execution device may also be wirelessly connected. The specific transmission mode is not limited in the present application as long as the information about the first pattern can be transmitted.

The embodiment of the present application provides the manufacturing method of a display panel. The detection device acquires the information about the first pattern and the execution device bonds the micro elements 2 according to the first pattern. More accurate bonding of the illuminated micro elements 2 after detection is achieved, the probability of occurrence of errors is reduced, and the yield of a product is improved.

In an optional embodiment, the detection device includes an optical lens and a display screen, the optical lens and the display screen are connected to each other. The step of using the detection device to acquire the information about the first pattern includes: scanning the each illuminated micro element 2 on the first temporary carrier plate 1 by using the optical lens, and displaying the each illuminated micro element 2 on the first temporary carrier plate 1 in the display screen so as to acquire the information about the first pattern.

Optionally, the optical lens may be an optical device such as a scanner; the optical lens focuses on the micro elements 2 on the first temporary carrier plate 1 to move to capture and acquire the illuminated micro elements 2 and transmit the position information of the illuminated micro elements 2 to the display screen, so that the first pattern is output.

The embodiment of the present application provides the manufacturing method of a display panel. The optical lens and the display screen are used. The first pattern illuminated on the first temporary carrier plate 1 is scanned, so that the capture accuracy of a micro element 2 is improved, more accurate information about the first pattern is obtained, and reliable guarantee is provided for a subsequent accurate and efficient bonding process.

In an optional embodiment, the execution device includes laser equipment, the first pattern includes a plurality of bonding regions, and the laser equipment irradiates a laser to the plurality of bonding regions so that the drive electrode 21 of the micro element 2 is bonded with the connection electrode 22.

Optionally, the execution device may be laser instrument. After the captured first pattern is transmitted to the execution device, the execution device needs to divide the first pattern into a plurality of bonding regions and bond the micro elements 2 according to different bonding regions. The specific number of bonding regions is not particularly limited in the present application.

The laser instrument is mainly used for laser welding the drive electrode 21 and the connection electrode 22 which are butted with each other. The drive electrode 21 and the connection electrode 22 are in a molten state under laser irradiation to form a fusion connection and then cured. Therefore, the bonding between the micro element 2 and the array substrate 20 is achieved. For example, the material of at least one of the drive electrode 21 or the connection electrode 22 includes a simple substance such as gold, tin, indium or the like or an alloy.

The specific structure of the execution device, the bonding principle and the number of execution devices are not particularly limited in the present application as long as the bonding process can be completed according to the information about the first pattern.

The embodiment of the present application provides the manufacturing method of a display panel. The first pattern is divided into a plurality of bonding regions. Commands are executed according to the plurality of bonding regions by using the laser instrument. The micro elements 2 are bonded more efficiently and pertinently. Finally, the first bonding pattern M is formed on the array substrate 20.

In an optional embodiment, the laser instrument irradiates the laser simultaneously to the plurality of bonding regions so that micro elements 2 in the plurality of bonding regions are simultaneously bonded; or the laser instrument irradiates, according to the information about the first pattern, lasers to the plurality of bonding regions one by one to bond micro elements 2.

Optionally, the corresponding amount of laser instrument may be provided according to the number of actually divided bonding regions. In order to more efficiently complete bonding according to the first pattern, bonding may be performed in the plurality of formed bonding regions simultaneously, and of course, bonding may be performed in the bonding regions one by one in a predetermined order.

The embodiment of the present application provides the manufacturing method of a display panel. On the basis of having a plurality of bonding regions, bonding is performed in the plurality of bonding regions simultaneously by using the laser instrument, thereby improving the bonding rate of the whole first pattern and making the molding process more efficient on the basis of pertinently completing the bonding in regions.

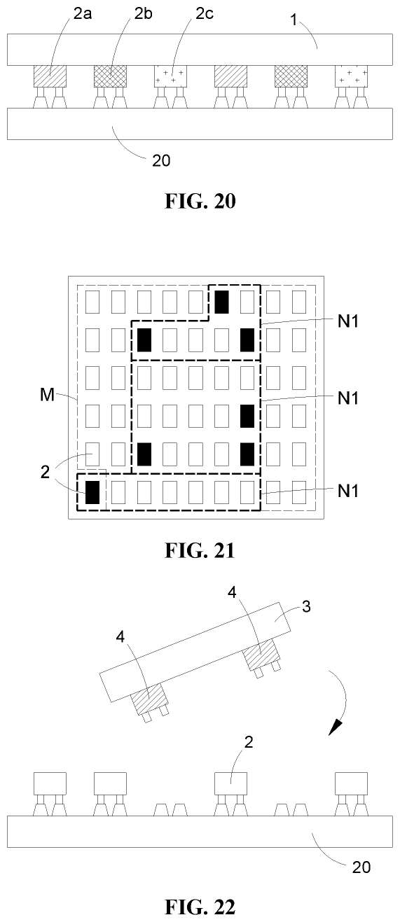

In an optional embodiment, with reference to FIG. 20, the plurality of micro elements 2 include a first element 2a, a second element 2b and a third element 2c, and the first element 2a, the second element 2b and the third element 2c have different light emission wavelengths and are spaced apart; and the drive electrode 21 of the micro element 2 being in contact with the connection electrode 22 on the array substrate 20 includes: a drive electrode 21 of the first element 2a, a drive electrode 21 of the second element 2b and a drive electrode 21 of the third element 2c being in contact with connection electrodes 22 on the array substrate 20, respectively.

Optionally, the first element 2a, the second element 2b, and the third element 2c are a red light-emitting element, a green light-emitting element and a blue light-emitting element, respectively. When the drive electrodes 21 of the micro elements 2 are in contact with the connection electrodes 22 on the array substrate 20, the first element 2a, the second element 2b, and the third element 2c are actually butted with the array substrate 20 separately.

Optionally, the first element 2a, the second element 2b, and the third element 2c each may have a different size and a different light-emitting area and are arranged according to a predetermined position array to meet different display requirements.

The embodiment of the present application provides the manufacturing method of a display panel. The first element 2a, the second element 2b and the third element 2c are butted with the array substrate 20 separately, so that different elements are separately detected, the detection accuracy of each light-emitting element is improved, and the lighting test of the micro element 2 is more targeted.

In an optional embodiment, the step of placing the first transfer substrate 10 and the array substrate 20 opposite to each other includes: simultaneously transferring the first element 2a, the second element 2b, and the third element 2c on the first temporary carrier plate 1 to the array substrate 20 and to be placed opposite to the array substrate 20.

The molded first element 2a, the molded second element 2b and the molded third element 2c are simultaneously transferred from the intermediate carrier plate to the first temporary carrier plate 1 and are jointly dropped onto the first temporary carrier plate 1 in a manner of micro element release through laser irradiation, achieving simultaneous transfer of the three elements.

The three elements are arranged on the first temporary carrier plate 1 according to the predetermined position array. The first transfer substrate 10 is moved to and butted with the array substrate 20. The power supply detection is performed for the three elements at the same time.

The embodiment of the present application provides the manufacturing method of a display panel. The first element 2a, the second element 2b, and the third element 2c are simultaneously transferred to the array substrate 20 and to be placed opposite to the array substrate 20, achieving simultaneous detection of all micro elements 2, simplifying the process flow and improving the overall preparation efficiency.

In an optional embodiment, the first element 2a on the first temporary carrier plate 1 is transferred to the array substrate 20 and placed opposite to the array substrate 20, and after the array substrate 20 is supplied with power, each illuminated first element 2a is acquired to form a first sub-pattern.

Transferring operations of the second element 2b and the third element 2c are repeatedly performed and after the power is supplied, each illuminated second element 2b is acquired to form a second sub-pattern, each illuminated third element 2c is acquired to form a third sub-pattern, and the first sub-pattern, the second sub-pattern and the third sub-pattern jointly form the first pattern.

In this embodiment, the three elements are separately transferred and supplied with power. That is, the first element 2a is placed on the first temporary carrier plate 1 first, butted with the array substrate 20, and then subjected to a power-on test. The illuminated first elements 2a form the first sub-pattern and are bonded.

Then, the first temporary carrier plate 1 is removed and the second elements 2b are placed on the first temporary carrier plate 1. The transfer and electrification process is repeated. The illuminated second elements 2b form the second sub-pattern. Then, the first temporary carrier plate 1 is removed again and the third elements 2c are placed on the first temporary carrier plate 1. The transfer and electrification process is repeated. The illuminated third elements 2c form the third sub-pattern. Finally, the first sub-pattern, the second sub-pattern and the third sub-pattern jointly form the first sub-pattern.

The embodiment of the present application provides the manufacturing method of a display panel. The first element 2a, the second element 2b and the third element 2c are separately transferred and supplied with power. The lighting test and bonding of the micro elements 2 are performed more pertinently. The detection of the micro elements 2 can be achieved more accurately. The detection error is reduced, and the whole process has higher accuracy.

In an optional embodiment, the first temporary carrier plate 1 has an unilluminated pattern complementary to the first sub-pattern, the second element 2b is placed on the first temporary carrier plate 1 and a supplementary first element 2a is placed at the unilluminated pattern, and the supplementary first element 2a and the second element 2b on the first temporary carrier plate 1 are transferred to the array substrate 20 and placed opposite to the array substrate 20.

After the first elements 2a are transferred and supplied with power, the illuminated first elements 2a form the first sub-pattern, and the unilluminated pattern complements the first sub-pattern. Therefore, when the first temporary carrier plate 1 is transferred for the second time, the second elements 2b may be placed on the first temporary carrier plate 1, and the supplementary first elements 2a may be placed at the positions corresponding to the unilluminated pattern at the same time, so that a supplementary test can be performed again at the unilluminated place of the first element 2a during the second transfer. Optionally and similarly, the test and bonding of the third elements 2c are completed in the preceding manner.

The embodiment of the present application provides the manufacturing method of a display panel. In the process of detecting and bonding the second element 2b, the unilluminated part of the first element 2a is supplemented. The two processes are combined into one at the same time, simplifying the process flow and improving the overall preparation efficiency.

In an optional embodiment, the step of providing the second transfer substrate 30 includes: removing the non-bonded micro element 2 on the first temporary carrier plate 1 by using a laser, and reconfiguring a micro element 2 to obtain the supplementary micro element 4, where the first temporary carrier plate 1 and the second temporary carrier plate 3 are a same carrier plate.

After the illuminated micro elements 2 are bonded according to the first pattern, the unilluminated micro element 2 on the removed first temporary carrier plate 1 may be removed by using the laser. After proper repair, the supplementary micro element 4 may be rearranged at the corresponding position, and the whole may be used as the second transfer substrate 30 to be butted with the array substrate 20 again for detection.

In this case, since the unilluminated micro element 2 is removed from the first temporary carrier plate 1 and the micro element 2 is rearranged on the first temporary carrier plate 1, the second transfer substrate 30 formed integrally is still the original first temporary carrier plate 1. That is, the first temporary carrier plate 1 and the second temporary carrier plate 3 are the same carrier plate.

The embodiment of the present application provides the manufacturing method of a display panel and a molding method of the second transfer substrate 30. The unilluminated micro element 2 is removed from the first temporary carrier plate 1 and a new micro element 2 is rearranged on the original first temporary carrier plate 1 for detection, saving materials used for the carrier plate and reducing the overall cost for materials.

In an optional embodiment, the step of providing the second transfer substrate 30 includes: replacing the first temporary carrier plate 1 and the non-bonded micro element 2, providing the second temporary carrier plate 3, and reconfiguring a micro element 2 on the second temporary carrier plate 3 to obtain the supplementary micro element 4.

In this embodiment, the removed first temporary carrier plate 1 and the unilluminated micro element 2 on the removed first temporary carrier plate 1 are not reused, the second temporary carrier plate 3 is provided, and the supplementary micro element 4 is placed at the corresponding position of the second temporary carrier plate 3. The pattern of the supplementary micro element 4 is complementary to the first pattern.

The embodiment of the present application provides the manufacturing method of a display panel. The first temporary carrier plate 1 is replaced with the second temporary carrier plate 3 and the supplementary micro element 4 is rearranged on the second temporary carrier plate 3. Another molding method of the second transfer substrate 30 is provided, thereby avoiding the removal and repair process for the first temporary carrier plate 1 and reducing the process difficulty.

In an optional embodiment, an area of the second temporary carrier plate 3 is less than an area of the first temporary carrier plate 1.

In the case where the positions of the first non-bonding pattern N on the array substrate 20 are concentrated in a certain region, the rearranged second temporary carrier plate 3 may have an area less than the first temporary carrier plate 1 and merely needs to completely cover the first non-bonding pattern N.

Optionally, as shown in FIG. 21, the first non-bonding pattern N may have a plurality of sub-regions N1, a plurality of second temporary carrier plates 3 are provided, and a relative position of a supplementary micro element 4 on one of the plurality of second temporary carrier plates 3 coincides with a pattern of any one of the plurality of sub-regions N1.

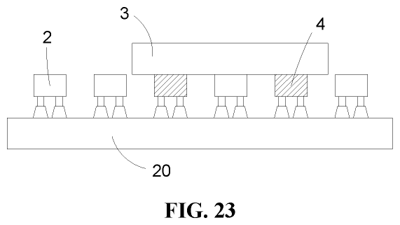

With reference to FIG. 22 and FIG. 23, local detection and bonding of the first non-bonding pattern N is achieved by using the plurality of second temporary carrier plates 3 corresponding to the plurality of sub-regions N1 of the first non-bonding pattern N. The plurality of second temporary carrier plates 3 may be spliced to form the shape of the first non-bonding pattern N, reducing the area of each second temporary carrier plate 3 relative to the first temporary carrier plate 1.

When the supplementary micro element 2 needs to be provided and bonded for the first non-bonding pattern N, each second temporary carrier plate 3 is transferred to a corresponding sub-region N1, and the supplementary micro element 4 on each second temporary carrier plate 3 is butted with the array substrate 20 and supplied with power. The illuminated micro elements 2 are detected and bonded until the first non-bonding pattern N is completely supplemented.

The embodiment of the present application provides the manufacturing method of a display panel. The area of the second temporary carrier plate 3 is less than the area of the first temporary carrier plate 1, so that the size of the carrier plate is reduced on the basis of replacing the temporary carrier plate, the materials used for the carrier plate are saved, the process cost is reduced, and the transfer and butt processes are conveniently completed, thus reducing the process difficulty.

The embodiment of the present application provides a laser apparatus used for receiving information about a first pattern provided by a detection device and providing a laser pattern corresponding to the first pattern to a target substrate according to the information about the first pattern.

The embodiments of the present application provide the manufacturing method of a display panel and the laser apparatus. A plurality of micro elements are transferred to the array substrate so that drive electrodes of the micro elements are in contact with connection electrodes on the array substrate. Power is supplied to the array substrate first. A lighting test is performed after the micro elements are conducted. Then, selectively, the illuminated micro elements are bonded. Therefore, the bonding process is more targeted, avoiding the case where the poor micro elements are removed after all the micro elements are bonded, thus reducing the process difficulty caused by later repair, simplifying the process flow steps, improving the preparation efficiency of the display panel, preventing damage to components in the process of removing the micro elements, and improving the overall yield of products.

Although the present application has been described with reference to preferred embodiments, various modifications may be made and components therein may be replaced with equivalents without departing from the scope of the present application. In particular, the various technical features mentioned in the various embodiments may be combined in any manner as long as there is no structural conflict. The present application is not limited to the specific embodiments disclosed herein but includes all technical solutions falling within the scope of the claims.

What is claimed is:

1. A manufacturing method of a display panel, comprising:
providing a first transfer substrate, wherein the first transfer substrate comprises a first temporary carrier plate and a plurality of micro elements disposed on the first temporary carrier plate, and a micro element of the plurality of micro elements comprises a drive electrode;
performing a detection and bonding process, comprising:
placing the first transfer substrate and an array substrate opposite to each other so that the drive electrode of the micro element is in contact with a connection electrode on the array substrate;
supplying power to the array substrate to conduct the plurality of micro elements;
acquiring a first pattern formed by each illuminated micro element, and bonding a drive electrode of the each illuminated micro element with the connection electrode according to the first pattern to form a first bonding pattern; and
removing the first temporary carrier plate to take away a non-bonded micro element to form a first non-bonding pattern on the array substrate;
providing a second transfer substrate, wherein the second transfer substrate comprises a second temporary carrier plate and a plurality of supplementary micro elements disposed on the second temporary carrier plate, and relative positions of the plurality of supplementary micro elements on the second transfer substrate are consistent with the first non-bonding pattern; and
performing the detection and bonding process again to provide a supplementary micro element of the plurality of supplementary micro elements for a position comprised in the first non-bonding pattern of the array substrate.

2. The manufacturing method of claim 1, wherein after the detection and bonding process is performed again, a second non-bonding pattern is formed on the array substrate, wherein the second non-bonding pattern is different from the first non-bonding pattern.

3. The manufacturing method of claim 1, further comprising:
configuring a temporary material layer on the first temporary carrier plate, and configuring the plurality of micro elements on the temporary material layer, wherein the temporary material layer has viscosity and elasticity;
wherein the placing the first transfer substrate and the array substrate opposite to each other comprises extruding the micro element with the temporary material layer so that the drive electrode of the micro element is in sufficient contact with the connection electrode on the array substrate.

4. The manufacturing method of claim 3, wherein the configuring the temporary material layer on the first temporary carrier plate comprises uniformly coating a material on the first temporary carrier plate to form the temporary material layer; or
dripping a material onto the first temporary carrier plate to form the temporary material layer in a manner of spin coating.

5. The manufacturing method of claim 3, wherein the configuring the temporary material layer on the first temporary carrier plate comprises controlling a thickness of the temporary material layer to remain at 5 μm to 20 μm.

6. The manufacturing method of claim 3,
before the removing the first temporary carrier plate to take away the non-bonded micro element, further comprising:
at least reducing viscosity of a position of the temporary material layer where a bonded micro element is located so that a bonding force between the micro element and the array substrate is greater than an adhesive force between the micro element and the temporary material layer.

7. The manufacturing method of claim 6, wherein at least reducing the viscosity of the position of the temporary material layer where the bonded micro element is located comprises: reducing viscosity of the entire temporary material layer and the viscosity of the temporary material layer being greater than zero.

8. The manufacturing method of claim 1, wherein
the acquiring the first pattern formed by the each illuminated micro element comprises:
using a detection device to acquire information about the first pattern; and
bonding the drive electrode of the each illuminated micro element with the connection electrode according to the first pattern comprises:
transmitting, by the detection device, the information about the first pattern to an execution device, and bonding, by the execution device, micro elements at positions corresponding to the first pattern according to the information about the first pattern.

9. The manufacturing method of claim 8, wherein the detection device comprises an optical lens and a display screen, the optical lens and the display screen are connected to each other, and the using the detection device to acquire the information about the first pattern comprises:
scanning the each illuminated micro element on the first temporary carrier plate by using the optical lens, and displaying the each illuminated micro element on the first temporary carrier plate in the display screen so as to acquire the information about the first pattern.

10. The manufacturing method of claim 8, wherein the execution device comprises laser equipment, the first pattern comprises a plurality of bonding regions, and the laser equipment irradiates a laser to the plurality of bonding regions so that the drive electrode of the micro element is bonded with the connection electrode.

11. The manufacturing method of claim 10, wherein the laser instrument irradiates the laser simultaneously to the plurality of bonding regions so that micro elements in the plurality of bonding regions are simultaneously bonded; or
the laser instrument irradiates, according to the information about the first pattern, lasers to the plurality of bonding regions one by one to bond micro elements.

12. The manufacturing method of claim 1, wherein the plurality of micro elements comprise a first element, a second element and a third element, and the first element, the second element and the third element have different light emission wavelengths and are spaced apart; and
the drive electrode of the micro element being in contact with the connection electrode on the array substrate comprises: a drive electrode of the first element, a drive electrode of the second element and a drive electrode of the third element being in contact with connection electrodes on the array substrate, respectively.

13. The manufacturing method of claim 12, wherein the placing the first transfer substrate and the array substrate opposite to each other comprises: simultaneously transferring the first element, the second element, and the third element on the first temporary carrier plate to the array substrate and to be placed opposite to the array substrate.

14. The manufacturing method of claim 12, wherein the first element on the first temporary carrier plate is transferred to the array substrate and placed opposite to the array substrate, and after the array substrate is supplied with power, each illuminated first element is acquired to form a first sub-pattern; and
transferring operations of the second element and the third element are repeatedly performed and after the power is supplied, each illuminated second element is acquired to form a second sub-pattern, each illuminated third element is acquired to form a third sub-pattern, and the first sub-pattern, the second sub-pattern and the third sub-pattern jointly form the first pattern.

15. The manufacturing method of claim 14, wherein the first temporary carrier plate has an unilluminated pattern complementary to the first sub-pattern, the second element is placed on the first temporary carrier plate and a supplementary first element is placed at the unilluminated pattern, and the supplementary first element and the second element on the first temporary carrier plate are transferred to the array substrate and placed opposite to the array substrate.

16. The manufacturing method of claim 1, wherein providing the second transfer substrate comprises: removing the non-bonded micro element on the first temporary carrier plate by using a laser, and reconfiguring a micro element to obtain the supplementary micro element, wherein the first temporary carrier plate and the second temporary carrier plate are a same carrier plate.

17. The manufacturing method of claim 1, wherein providing the second transfer substrate comprises: replacing the first temporary carrier plate and the non-bonded micro element, providing the second temporary carrier plate, and reconfiguring a micro element on the second temporary carrier plate to obtain the supplementary micro element.

18. The manufacturing method of claim 17, an area of the second temporary carrier plate is less than an area of the first temporary carrier plate.

19. The manufacturing method of claim 18, wherein the first non-bonding pattern has a plurality of sub-regions, a plurality of second temporary carrier plates are provided, and a relative position of a supplementary micro element on one of the plurality of second temporary carrier plates coincides with a pattern of any one of the plurality of sub-regions.

20. A detection and bonding apparatus for a micro element, comprising a detection device and an execution device;
wherein the detection device comprises an optical lens and a display screen, the optical lens and the display screen are connected to each other, and the detection device is configured to acquire information about a first pattern formed by a position of each illuminated micro element; and
wherein the execution device comprises laser instrument and is configured to receive the information about the first pattern provided by the detection device and to bond a micro element at a corresponding position according to the information about the first pattern.
